(19) United States
(12) Patent Application Publication
(10) Pub. No.: US 2022/0209222 A1
(43) Pub. Date: Jun. 30, 2022

(54) Method and System for High-Yield Dynamic Crystallization Manufacturing of Battery Materials

(71) Applicant: eJoule, Inc., Fremont, CA (US)

(72) Inventors: Yan Wang, Sunnyvale, CA (US); Liang-Yuh Chen, Saratoga, CA (US); Yu-Chien Tseng, New Taipei City (TW); Li-Jui Liu, Hsinchu County (TW); Yong-Fen Huang, Pingtung County (TW)

(21) Appl. No.: 17/137,247

(22) Filed: Dec. 29, 2020

(51) Int. Cl. H01M 4/1395; H01M 10/0525; H01M 4/134; H01M 4/66; C23C 14/14

(52) U.S. Cl. CPC H01M 4/1395; H01M 10/0525; C23C 14/14; H01M 4/664; H01M 4/134

(57) ABSTRACT

A processing system and method for high-yield dynamic crystallization and processing of a battery material are provided. The processing system may include a feeder assembly, a reaction chamber, a heating assembly, a gas delivery assembly, a gas exhaust assembly, a collection assembly, and a lift mechanism being connected to a support platform and adapted to lift the support platform at an α angle of more than 0° and no more than 10°. The reaction chamber includes an outer tube made of a stainless-steel material, an inner tube made of a ceramic material, and a chamber housing enclosed by the inner tube. One or more gear assemblies are connected to the outer tube and adapted to rotate the reaction chamber so that the inner tube and the outer tube of the reaction chamber are in a rotational movement around a center axis within the chamber housing of the reaction chamber.

### FIELD OF THE INVENTION

This invention generally relates to a processing system and method for high yield dynamic crystallization manufacturing of battery materials.

### BACKGROUND OF THE INVENTION

Great efforts have been devoted to the development of advanced electrochemical battery cells to meet the growing demand of various consumer electronics, electrical vehicles and grid energy storage applications in terms of high energy density, high power performance, high capacity, long cycle life, low cost and excellent safety. In most cases, it is desirable for a battery to be miniaturized, light-weighted and rechargeable (thus reusable) to save space and material resources.

In an electrochemically active battery cell, a cathode and an anode are immersed in an electrolyte and electronically separated by a separator. The separator is typically made of porous polymer membrane materials such that metal ions released from the electrodes into the electrolyte can diffuse through the pores of the separator and migrate between the cathode and the anode during battery charge and discharge. The type of a battery cell is usually named from the metal ions that are transported between its cathode and anode electrodes. Various rechargeable secondary batteries, such as nickel cadmium battery, nickel-metal hydride battery, lead acid battery, lithium ion battery, and lithium ion polymer battery, etc., have been developed commercially over the years. To be used commercially, a rechargeable secondary battery is required to be of high energy density, high power density and safe. However, there is a trade-off between energy density and power density.

Lithium ion battery is a secondary battery which was developed in the early 1990s. As compared to other secondary batteries, it has the advantages of high energy density, long cycle life, no memory effect, low self-discharge rate and environmentally benign. Lithium ion battery rapidly gained acceptance and dominated the commercial secondary battery market. However, the cost for commercially manufacturing various lithium battery materials is considerably higher than other types of secondary batteries.

In a lithium ion battery, the electrolyte mainly consists of lithium salts (e.g., LiPF6, LiBF4 or LiClO4) in an organic solvent (e.g., ethylene carbonate, dimethyl carbonate, and diethyl carbonate) such that lithium ions can move freely therein. In general, aluminum foil (e.g., 15″20 μm in thickness) and copper foil (e.g., 8″15 μm in thickness) are used as the current collectors of the cathode electrode and the anode electrode, respectively. For the anode, micron-sized graphite (having a reversible capacity around 330 mAh/g) can be used as the active material coated on the anode current collector. Graphite materials are often prepared from solid-state processes, such as grinding and pyrolysis at extreme high temperature without oxygen (e.g., graphitization at around 3000° C.). As for the active cathode materials, various solid materials of different crystal structures and capacities have been developed over the years. Examples of good cathode active materials include nanometer- or micron-sized lithium transition metal oxide materials and lithium ion phosphate, etc.

Cathode active materials are the most expensive component in a lithium ion battery and, to a relatively large extent, determines the energy density, cycle life, manufacturing cost and safety of a lithium battery cell. When lithium battery was first commercialized, lithium cobalt oxide (LiCoO₂) material is used as the cathode material and it still holds a significant market share in the cathode active material market. However, cobalt is toxic and expensive. Other lithium transition metal oxide materials, such as layered structured LiMeO₂ (where the metal Me=Ni, Mn, Co, etc.; e.g., LiNi_{0.33}Mn_{0.33}Co_{0.33}O₂, with their reversible/practical capacity at around 140″150 mAh/g), spinel structured LiMn₂O₄ (with reversible/practical capacity at around 110-120 mAh/g), and olivine-type lithium metal phosphates (e.g., LiFePO₄, with reversible/practical capacity at around 140″150 mAh/g) have recently been developed as active cathode materials. When used as cathode materials, the spinet structured LiMn₂O₄ materials exhibit poor battery cycle life and the olivine-type LiFePO₄ materials suffer from low energy density and poor low temperature performance. As for LiMeO₂ materials, even though their electrochemical performance is better, prior manufacturing processes for LiMeO₂ can obtain mostly agglomerates, such that the electrode density for most LiMeO₂ materials is lower as compared to LiCoO₂. In any case, prior processes for manufacturing materials for battery applications, especially cathode active materials, are too costly as most processes consumes too much time and energy, and still the qualities of prior materials are inconsistent and manufacturing yields are low.

Conventional material manufacturing processes such as solid-state reaction (e.g., mixing solid precursors and then calcination) and wet-chemistry processes (e.g., treating precursors in solution through co-precipitation, sol-gel, or hydrothermal reaction, etc., and then mixing and calcination) have notable challenges in generating nano- and micron-structured materials. It is difficult to consistently produce uniform solid materials (i.e., particles and powders) at desired particle sizes, morphology, crystal structures, particle shape, and even stoichiometry.

Most conventional solid-state reactions require long calcination time (e.g., 4-20 hours) and additional annealing process for complete reaction, homogeneity, and grain growth. For example, spinel structured LiMn₂O₄ and olivine-type LiFePO₄ materials manufactured by solid-state reactions require at least several hours of calcination, plus a separate post-heating annealing process (e.g., for 24 hours), and still showing poor quality consistency. One intrinsic problem with solid-state reaction is the presence of temperature and chemical (such as O₂) gradients inside a calcination furnace, which limits the performance, consistency and overall quality of the final products.

On the other hand, wet chemistry processes performed at low temperature usually involve faster chemical reactions, but a separate high temperature calcination process and even additional annealing process are still required afterward. In addition, chemical additives, gelation agents, and surfactants required in a wet chemistry process will add to the material manufacturing cost (in buying additional chemicals and adjusting specific process sequence, rate, pH, and temperature) and may interfere with the final composition of the as-produced active materials (thus often requiring additional steps in removing unwanted chemicals or filtering products). Moreover, the sizes of the primary particles of the product powders produced by wet chemistry are very small, and tend to agglomerates into undesirable large sized secondary particles, thus affecting energy packing density. Also, morphologies of the as-produced powder particles often exhibit undesirable amorphous aggregates, porous agglomerates, wires, rods, flakes, etc. Uniform particle sizes and shapes allowing for high packing density are desirable.

The synthesis of lithium cobalt oxide (LiCoO₂) materials is relatively simple and includes mixing a lithium salt (e.g., lithium hydroxide (LiOH) or lithium carbonate (Li₂CO₃)) with cobalt oxide (Co₃O₄) of desired particle size and then calcination in a furnace at a very high temperature for a long time (e.g., 20 hours at 900° C.) to make sure that lithium metal is diffused into the crystal structure of cobalt oxide to form proper final product of layered crystal structured LiCoO₂ powders. This approach does not work for LiMeO₂ since transition metals like Ni, Mn, and Co does not diffuse well into each other to form uniformly mixed transition metal layers if directly mixing and reacting (solid-state calcination) their transition metal oxides or salts. Therefore, conventional LiMeO₂ manufacturing processes requires buying or preparing transitional metal hydroxide precursor compounds (e.g., Me(OH)₂. Me=Ni, Mn, Co, etc.) from a co-precipitation wet chemistry process prior to making final active cathode materials (e.g., lithium NiMnCo transitional metal oxide (LiMeO₂)).

Since the water solubility of these Ni(OH)₂, Co(OH)₂, and Mn(OH)₂ precursor compounds are different and they normally precipitate at different concentrations, the pH of a mixed solution of these precursor compounds has to be controlled and ammonia (NH₃) or other additives has to be added slowly and in small aliquots to make sure nickel (Ni), manganese (Mn), and cobalt (Co) can co-precipitate together to form micron-sized nickel-manganese-cobalt hydroxide (NMC(OH)₂) secondary particles. Such co-precipitated NMC(OH)₂ secondary particles are often agglomerates of nanometer-sized primary particles. Therefore, the final lithium NMC transitional metal oxide (LiMeO₂) made from NMC(OH)₂ precursor compounds are also agglomerates. These agglomerates are prone to break under high pressure during electrode calendaring step and being coated onto a current collector foil. Thus, when these lithium NMC transitional metal oxide materials are used as cathode active materials, relatively low pressure has to be used in calendaring step, and further limiting the electrode density of a manufactured cathode.

In conventional manufacturing process for LiMeO₂ active cathode materials, precursor compounds such as lithium hydroxide (LiOH) and transitional metal hydroxide (Me(OH)₂ are mixed uniformly in solid-states and stored in thick Al₂O₃ crucibles. Then, the crucibles are placed in a heated furnace with 5-10° C./min temperature ramp up speed until reaching 900° to 950° C. and calcinated for 10 to 20 hours. Since the precursor compounds are heated under high temperature for a long time, the neighboring particles are sintered together, and therefore, a pulverization step is often required after calcination. Thus, particles of unwanted sizes have to be screened out after pulverization, further lowering down the overall yield.

The high temperature and long reaction time also lead to vaporization of lithium metals, and typically requiring as great as 10% extra amount of lithium precursor compound being added during calcination to make sure the final product has the correct lithium/transition metal ratio. Overall, the process time for such a multi-step batch manufacturing process will take up to a week so it is very labor intensive and energy consuming. Batch process also increases the chance of introducing impurity with poor run-to-run quality consistency and low overall yield.

Exemplary cathode materials for lithium battery include lithium cobalt oxide (LiCoO₂), lithium manganese oxide (LiMnO₂), and lithium iron phosphate (LiFePO₄) ternary materials. Most conventional processes for manufacturing these cathode materials include many steps of mixing, heating by pushing plate roller furnaces, sintering furnaces, coarsely crushing, being finely pulverized, screening, de-ironing, and final packaging, most likely conducted in batch processing, not in a continuous manner. Also, the largest energy-consuming step is processing by a sintering furnace (e.g., a push plate furnace or a roller furnace), and its process is static in nature with such disadvantages in costing a large amount of sintered energy, long cycle life, short chamber lifetime, complicated operation steps, low production efficiency, uneven heating, difficulty to control cooling time such that the resulting battery materials are either over heated or not being heated enough.

Few manufacturers use a continuous rotary kiln, but a continuous rotary kiln has two major problems. First, since the sizes of the powder particles are very small, usually 0.1 micron to 50 microns, it is very easy for the battery material powder particles to adhere on the inside wall of the kiln (i.e., furnace or chamber) and it could produce impurities, defective product materials, and contaminants after a long residence time. Second, when the furnace is in contact with the battery material, it would be easy to introduce harmful metallic impurities (Pb, Zn, Cu, Fe, etc.), which could lead to self-discharge of the lithium battery and safety hazards when the battery material are packaged into battery cells. Since the push plate roller furnace or the sintering furnace is static in nature, the final product is easy to agglomerate, and then there must have further steps to coarsely crush and finely pulverize the battery materials. In addition, most conventional processes are manually operated in different processing stages. Further, proper crystallization of the powders or particles of the battery materials are often laborious and not ideal.

Thus, there is a need for an improved method and system to dynamically manufacture high quality, properly crystalized, structured active materials for a batter cell.

### SUMMARY OF THE INVENTION

This invention generally relates to processing systems and methods of heating solid battery material compounds to prevent particle impurity and contaminations during high temperature annealing and particle crystallization of battery materials. More specifically, the invention related to method and processing system for producing material particles (e.g., active electrode materials, etc.) in desirable crystal structures, sizes and morphologies.

In one embodiment, a processing system of manufacturing battery materials includes a reaction chamber having an outer tube being made of a stainless-steel material, and an inner tube being made of a ceramic material, and a chamber housing enclosed by the inner tube and provided for processing one or more solid compounds. In one aspect, the processing system also includes a feeder assembly being connected to a front end of the reaction chamber and adapted to deliver the one or more solid compounds into the chamber housing within the reaction chamber, a heating assembly being adapted to cover and surround an outer portion of the reaction chamber, and provide heating energy and structural support to the reaction chamber.

In another aspect, the processing system further includes one or more gear assemblies being connected to the outer chamber tube and adapted to rotate the reaction chamber so that the inner tube and the outer tube of the reaction chamber being in a rotational movement around a center axis within the chamber housing of the reaction chamber. In still another aspect, the processing system may further include a collection assembly being connected to a rear end of the reaction chamber and adapted to collect one or more processed battery materials from the reaction chamber.

In another embodiment, a processing system of manufacturing battery materials includes a reaction chamber having an outer tube being made of a stainless-steel material and an inner tube being made of a ceramic material, and a chamber housing being enclosed by the inner tube and provided for processing one or more solid compounds, and a feeder assembly being sealably connected to a front end of the reaction chamber and adapted to deliver the one or more solid compounds into the chamber housing within the reaction chamber. In addition, the processing system may also include a heating assembly, one or more gear assemblies being connected to the outer tube and adapted to rotate the inner tube and the outer tube of the reaction chamber, and a collection assembly being sealably connected to a rear end of the reaction chamber and adapted to collect processed battery materials from the reaction chamber. The processing system may further include a gas supply assembly having a gas inlet and a gas supply tube for supplying one or more gases into the chamber housing of the reaction chamber, and a gas exhaust assembly having a gas outlet and a gas exhaust tube being made of a ceramic material for delivering one or more gases out of the chamber housing of the reaction chamber.

In still another embodiment, a processing system of manufacturing battery materials is provided and includes a reaction chamber, a feeder assembly, a heating assembly, one or more gear assemblies being connected to the outer tube and adapted to rotate the inner tube and the outer tube of the reaction chamber in a rotational movement around a center axis within the chamber housing of the reaction chamber, and a support platform being adapted to support the reaction chamber of the processing system. In one aspect, a lift mechanism is connected to the support platform and adapted to lift the support platform at an α angle; wherein the α angle is more than 0° and no more than 10°.

In a further embodiment, a method for manufacturing a battery material, includes delivering one or more solid compounds into a feeder assembly of a processing system, and feeding the one or more solid compounds from the feeder assembly to a chamber housing inside a reaction chamber of the processing system to be processed inside the chamber housing of the reaction chamber. In one aspect, the reaction chamber includes an outer tube being made of a stainless-steel material, and an inner tube being made of a ceramic material. In another aspect, the processing system includes the feeder assembly, the reaction chamber, a heating assembly having one or more heating elements to continuously provide heating energy to the reaction chamber, a gas supply assembly adapted to supply one or more gases into the chamber housing of the reaction chamber, and a gas exhaust assembly adapted to deliver one or more gases out of the chamber housing of the reaction chamber; and a collection chamber.

In one aspect, the method also include continuously rotating the inner tube and the outer tube of the reaction chamber in a rotational movement around a center axis within the chamber housing of the reaction chamber, and continuously and rotatably moving the one or more solid compounds inside the chamber housing being enclosed by the inner tube of the reaction chamber. In addition, the one or more solid compounds are continuously heated and processed within the chamber housing at a high temperature between 300° C. and 1,000° C., and processed battery materials are collected from the collection assembly of the processing system.

### BRIEF DESCRIPTION OF THE DRAWINGS

So that the system in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A illustrates a perspective view of one embodiment of an exemplary processing system for employing in a method of preparing a battery material.

FIG. 1B illustrates a side cross-sectional view of a front part of one embodiment of an exemplary processing system useful in preparing a battery material for a battery electrochemical cell.

FIG. 1C illustrates a side cross-sectional view of a rear part of one embodiment of an exemplary processing system useful in preparing a battery material for a battery electrochemical cell.

FIG. 2 illustrates a perspective view of another exemplary processing system that can be used in a method of preparing a battery material according to another embodiment of the invention.

FIG. 3A illustrates an enlarged front cross-sectional view of an exemplary reaction chamber with its chamber housing being rotated in a counterclockwise movement.

FIG. 3B illustrates an enlarged front cross-sectional view of an exemplary reaction chamber with its chamber housing being rotated in a clockwise movement.

FIG. 4A illustrates an enlarged front cross-sectional view of one example of a heating assembly and the reaction chamber.

FIG. 48 illustrates an enlarged front cross-sectional view of another example of a heating assembly and the reaction chamber.

FIG. 5 illustrates one embodiment of a flow chart of a method of preparing a battery material using one or more processing systems of the invention.

### DETAILED DESCRIPTION

The present invention generally provides a high-yield dynamic processing system and a method thereof for manufacturing battery materials. The processing system generally includes a reaction chamber, a feeder assembly, a heating assembly, one or more gear assemblies, and a collection assembly. The processing system is placed at a support platform with one side lifted by a lift mechanism from the ground at an angle of a degree; and the a degree could be more than 0° and no more than 10°. Solid compounds are continuously delivered into the processing system and processed dynamically through various plenums of the in-line processing and reaction modules within the reaction chamber of the processing system such that the solid compounds can be processed and formed into properly crystalized, processed battery material particles. Thus, a method and system for high-yield continuous dynamic crystallization manufacturing of battery materials is provided.

In one embodiment, the processing system may also include a gas supply assembly, and a gas exhaust assembly. Air or gas is served as the energy source for conducting one or more chemical reactions on compounds to be processed inside the reaction chamber. The processing system is useful in performing a continuous process for manufacturing battery materials, and solves the problems of high manufacturing cost, low yield, poor quality consistency, low electrode density, and low energy density as seen in conventional active material manufacturing processes.

In one aspect, one or more solid compounds are continuously delivered into the reaction chamber through the feeder assembly for dynamic processing high temperature annealing and proper crystallization. For example, the reaction chamber may be used to process solid compounds into processed battery materials, such as active cathode material particles, and other materials. The processed battery materials, i.e., battery material particles, are then cooled by one or more cooling elements and collected by the collection assembly. Accordingly, a continuous dynamic material crystallization process is performed within the processing system to obtain high quality and consistent active battery materials with much less time, labor, and supervision than materials prepared from conventional manufacturing processes.

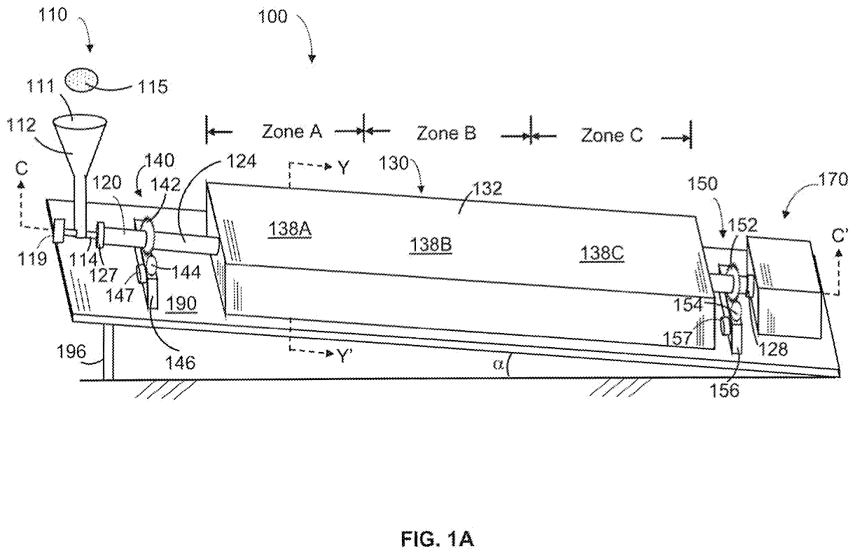

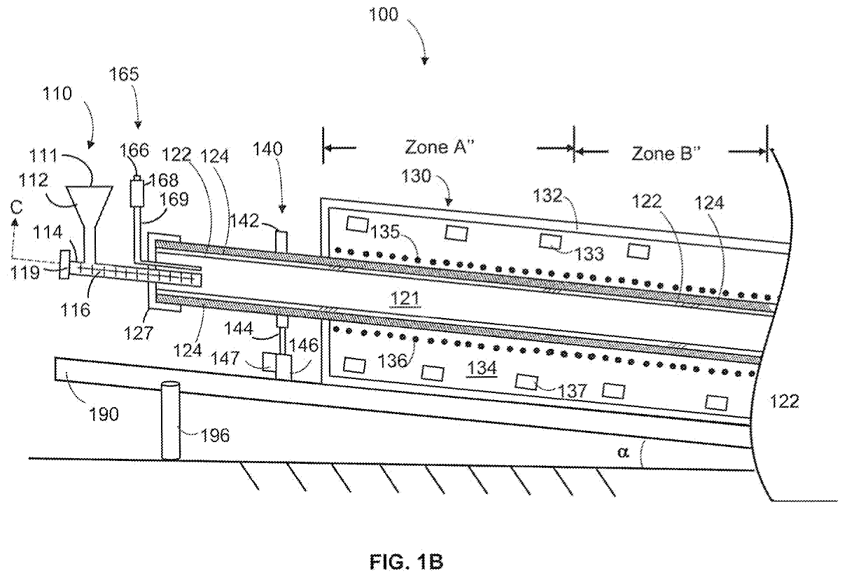

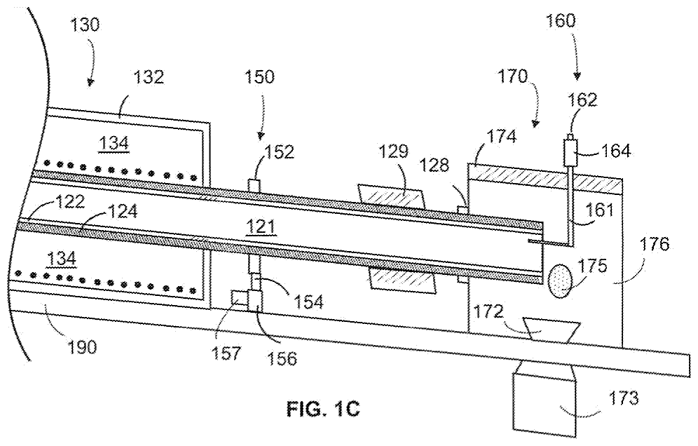

FIG. 1A illustrates one example of a processing system 100 for processing one or more solid compounds 115 and producing processed battery materials useful in battery electrochemical cells. FIG. 18 is a side cross-sectional view of one example of a front portion of the processing system 100 and FIG. 1C is a side cross-sectional view of another example of a rear portion of the processing system 100. As shown in FIG. 1A, the processing system 100 may generally include a feeder assembly 110, a reaction chamber 120, a heating assembly 130, a front gear assembly 140, a rear gear assembly 150 and a collection assembly 170.

In one aspect, the reaction chamber 120 is provided for processing the one or more solid compounds 115 at high temperature to obtain proper annealing and crystallization of processed battery materials in high yield. In another aspect, the reaction chamber 120 includes an outer tube 124, an inner tube 122, and a chamber housing 121 being enclosed by the inner tube 122. In one embodiment, the walls of the inner tube 122 are made of a ceramic material or other suitable materials that are not reactive to the one or more solid compounds 115. Suitable materials may include, but are not limited to, alumina ceramics, aluminum oxide (Al₂O₃), ceramic materials with high purity of alumina (e.g., more than 90% purity of alumina, such as more than 95% of alumina, etc). In another embodiment, the walls of the outer tube 124 can be made of any metal materials that provide structural support and strength. For example, the outer tube 124 can be comprised of a stainless-steel material, or other suitable chamber wall materials.

Firstly, the one or more solid compounds 115 are delivered into the feeder assembly 110 through a feeder inlet 111. For example, the one or more solid compounds 115 can be delivered manually (e.g., in separate batches) or continuously (e.g., batch by batch one after another or by an automation machinery). Solid compounds that require further processing for the purpose of calcination, annealing, and or other types of processing are not limited and may include but are not limited to nanometer- or micron-sized lithium transition metal oxide materials and lithium ion phosphate, such as metal oxide materials, lithium-containing metal oxide compounds, lithium cobalt-containing oxide compounds, lithium manganese-containing oxide compounds, lithium nickel-containing oxide compounds, lithium aluminum-containing oxide compounds, lithium magnesium-containing oxide compounds, lithium transition metal oxide materials, LiMeO₂ (where the metal Me=Ni, Mn, Co, Mg, Al, and combinations thereof, etc.; e.g., LiNiₓMn_{y}Co_{z}O₂, LiNi_{0.33}Mn_{0.33}Co_{0.33}O₂, lithium cobalt oxide (LiCoO₂), lithium cobalt oxide (LiCoO₂), lithium cobalt oxide (LiCoO₂), etc.), lithium metal phosphates (e.g., lithium iron phosphates LiFePO₄ olivine-type or other types), and combinations thereof, among others.

Exemplary metal oxide materials include, but are not limited to, lithium cobalt oxide (e.g., LiₓCo_{y}O₂), lithium nickel cobalt oxide (e.g., LiₓNi_{y}Co_{z}O₂), lithium nickel manganese oxide (e.g., LiNi_{y}Mn_{z}O₂, LiₓNi_{y}MnₓO₄, etc.), lithium nickel manganese cobalt oxide (e.g., LiₐNi_{b}Mn_{c}Co_{d}Oₑ in layered structures or layered-layered structures; and/or LiNiₓMn_{y}Co_{z}O₂, a NMC oxide material where x+y+z=1, such as LiNi_{0.33}Mn_{0.33}Co_{0.33}O₂, LiNi_{0.6}Mn_{0.2}Co_{0.2}O₂, LiNi_{0.5}Mn_{0.3}Co_{0.2}O₂, LiNi_{0.4}Mn_{0.4}Co_{0.2}O₂, LiNi_{0.7}Mn_{0.15}Co_{0.15}O₂, LiNi_{0.5}Mn_{0.5}Co_{0.1}O₂, etc.; and/or a mixed metal oxide with doped metal, among others. Other examples include lithium cobalt aluminum oxide (e.g., LiₓCo_{y}Al_{z}Oₙ), lithium nickel cobalt aluminum oxide (e.g., LiₓNi_{y}Co_{z}AlₐO_{b}), sodium iron manganese oxide (e.g., NaₓFe_{y}Mn_{z}O₂), among others. In another example, a mixed metal oxide with doped metal is obtained; for example. Liₐ(NiₓMn_{y}Co_{z})MeO_{b} (where Me=doped metal of Al, Mg, Fe, Ti, Cr, Zr, C, or combinations thereof), Liₐ(NiₓMn_{y}Co_{z})MeO_{b}Fc (where Me=doped metal), among others.

Other metal oxide materials containing one or more lithium (Li), nickel (Ni), manganese (Mn), cobalt (Co), aluminum (Al), titanium (Ti), sodium (Na), potassium (K), rubidium (Rb), vanadium (V), cesium (Cs), copper (Cu), magnesium (Mg), iron (Fe), among others, can also be obtained. In addition, the metal oxide materials can exhibit a crystal structure of metals in the shape of layered, spinel, olivine, etc. In addition, the morphology of the final reaction product F₄ exists as desired solid powders. The particle sizes of the solid powders range between 10 nm and 100 um.

The one or more solid compounds 115 to be processed may be any of suitable battery cathode and or anode materials that are in different layered structures, spinel structures or olivine structures. The one or more solid compounds 115 that can be processed by the processing system 100 may require high temperature processing and annealing in order to achieve their proper oxidization states, in their proper nano-sized structures, or in their proper crystallization forms, and remove unwanted impurities.

FIGS. 1A-1B illustrate one example of a feeder assembly 110. The feeder assembly 110 may include a feeder bucket 112, a feeder tube 114, and a spiral rod 116. A feeder bucket 112 is connected to a feeder tube 114. In one aspect, a spiral rod 116 is positioned inside the feeder tube 114. The feeder bucket 112 is dischargeable. The feeder bucket 112 is adapted to receive one or more solid compounds 115, whereas the feeder tube 114 is connected to the feeder bucket 112 and is adapted to receive the one or more solid compounds 115 from the feeder bucket 112.

The spiral rod 116 within the feeder tube 114 is adapted to be rotating for carrying the one or more solid compounds 115 into the reaction chamber 120 (e.g., inside the chamber housing 121). A motor 119 is connected to one end of the feeder tube 114 to control the rotational movement of the spiral rod 116 within the feeder tube. The spiral rod 116 is adapted to be rotating for carrying the one or more solid compounds 115 into the chamber housing 121 of the reaction chamber 120.

In general, the feeder bucket 112, the feeder tube 114, and the spiral rod 116 can each be made of any metal materials. In one embodiment, the feeder bucket 112, the feeder tube 114, and the spiral rod 116 can each primary be made of a nickel-containing material. In another embodiment, the nickel-containing material is nickel at high purity, such as at a purity of more than 95% pure nickel, or 99% nickel or 100 pure nickel, among others.

Not wishing to be bound by theory, it is contemplated that traditional stainless-steel material may easily be reacted to the materials to be processed (i.e., one or more solid compounds 115) by the processing system 100. The use of a nickel-containing material as the material for the feeder bucket 112, the feeder tube 114, and the spiral rod 116 is employed in order to prevent unwanted reaction of the one or more solid compounds 115 with the materials of these components and accumulation of contaminations and impurities, etc., within the feeder assembly 110, among others.

The rear portions of the feeder tube 114 and the spiral rod 116 are positioned and inserted into the inside of the chamber housing 121 of the reaction chamber 120. The connection between the feeder tube 114 and the front end of the reaction chamber 120 can be sealed by a sealing mechanism, e.g., a front-end seal 127, or other type of seals, etc., to ensure the pressure within the chamber housing 121 can be controlled during battery material processing, while keeping the reaction chamber 120 in clockwise or counterclockwise rotational motions.

As illustrated in FIGS. 1A-1C, the front gear assembly 140 of the processing system 100 is positioned near a front-end portion of the reaction chamber 120, while the rear gear assembly 150 is positioned near a rear-end portion of the reaction chamber 120 for supporting the weight and movement of the reaction chamber 120. The front gear assembly 140 and the rear gear assembly 150 are connected the outer tube 124 of the reaction chamber 120 and are adapted to rotate the reaction chamber 120 in a rotational movement around a center axis (e.g., LINE C-C′) within the chamber housing 121 of the reaction chamber 120.

In one aspect, the front gear assembly 140 may generally include one or more gears 142, 144 and a motor 147. In another aspect, the rear gear assembly 150 may include one or more gear 152, 154, and optionally, a motor 157. One or both of the motors 147, 157 may be used to drive the movement of the one or more gears 142, 144 for rotating the reaction chamber 120 of the processing system 100, e.g., around a center axis (Line C-C′) within the chamber housing 121 of the reaction chamber 120 to control the rotational movement of the outer tube 124 and inner tube 122 of the reaction chamber 120 through the one or more gears 142, 144, 152, 154.

In one aspect, only one motor (e.g., the motor 147 or the motor 157) are used to drive the gears and control the rotational movement of the reaction chamber 120. For example, the motor 147 positioned near the front end portion may be employed to drive and control the rotational movement of the reaction chamber 120 and leaving the rear end portion of the reaction chamber freely moving without the constraint and control of another rea end motor. For example, the outer tube 124 and the inner tube 122 of the reaction chamber 120 may be controlled by one motor at one end portion, allowing so the other end portion to be freely rotating and freely expanding in length, which may be caused by thermal expansion of the materials of the walls of a reaction chamber at high processing temperature, etc.

Optionally, the one or more gears 142, 144 can be supported by one or more gear bases 146, while the one or more gears 152, 154 can be supported by one or more gear bases 156. Both gear bases 146, 156 can be positioned on a support platform or on ground. Thus, in one embodiment, the front gear assembly 140 and the rear gear assembly 150 are positioned on a support platform 190 within the processing system 100. Below the support platform 190, a lift mechanism 196 may be positioned and connected to a front side of the support platform 190 and adapted to lift one end of of the support platform 190 in a vertical direction at an α angle higher than another end of the support platform 190, as shown in FIGS. 1A-1B.

In one embodiment, the lifting of the support platform 190 one end higher than the other end and at a angle (e.g., a front end at or near the feeder assembly 110 is positioned vertically higher than a rear end at or near the rear gear assembly 150 provides for the ease of delivering the one or more solid compounds 115 into the chamber housing 121 and assists in moving the one or more solid compounds 115 along the length of the reaction chamber. For example, the use of the lift mechanism 196 may as assist in delivering and moving the one or more solid compounds 115 from one end of the reaction chamber 120 to another end of the reaction chamber 120 in a continuous movement path within the chamber housing 121. In one aspect, the α angle can be any degree less than 90°. As an example, the a angle can be more than 0° and no more than 10°. As another example, the α angle can be between 2° and 7°. It is contemplated to lift at least a portion of the processing system 100 in order to promote the movement of the one or more solid compounds 115 through the whole processing system 100.

Not wishing to be bound by theory, it is contemplated that the position of the support platform 190 at a angle is provided to provide a gravity force and help to increase the delivery speed and assist in “continuous” processing of the one or more solid compounds 115 within the inner tube of the reaction chamber, whereas the rotational movement of the inner tube and outer tube of the reaction chamber help to promote the rotation of solid compounds 115 around a center axis within the chamber housing of the reaction chamber and assist in “dynamic” processing of the one or more solid compounds 115.

Processing of the one or more solid compounds 115 inside the chamber housing 121 of the reaction chamber are further assisted by the delivering of one or more reaction gases (e.g., air, oxygen gas (O₂), nitrogen gas (N₂), hydrogen gas (H₂), and other reactive and/or non-reactive gases, among others) to promote complete chamber reactions and proper “crystallization” of the solid compounds 115 processed within the reaction chamber. The reaction gases can be delivered into the reaction chamber 120 via a gas supply assembly 160 and out of the reaction chamber 120 via a gas exhaust assembly 165, as shown in FIGS. 1A-1C.

The gas supply assembly 160 and the gas exhaust assembly 165 can be connected to suitable parts of the chamber housing 121 (e.g., near its front end and or b its back end parts, or vice versa.) In one embodiment, the gas exhaust assembly 165 is disposed at or near the front end of the reaction chamber 120, which is higher in vertical direction than its rear end, while the gas supply assembly 160 is disposed at or near the rear end of the reaction chamber 120, which is lower in vertical direction than its front end due the lifting of the reaction chamber at a angel by the lift mechanism 190.

The gas supply assembly 160 includes a gas inlet 162, a flow rate meter 164 and a gas supply tube 161. The gas supply tube 161 extends into the chamber housing 121 of the reaction chamber 120 adapted to supply one or more reactive and non-reactive gases into the chamber housing 121 of the reaction chamber 120. The gas exhaust assembly 165 may include a gas outlet 166, a gas exhaust rate meter 168 and a gas exhaust tube 169. The gas exhaust tube 169 extends into the chamber housing 121 of the reaction chamber 120 and is adapted to deliver one or more gases out of the chamber housing 121 of the reaction chamber 120.

In one embodiment, one or more gases (e.g., air, oxygen gas (02), etc.) are delivered via the gas supply assembly 160 to promote processing of battery materials by oxidization inside the chamber housing 121 of the reaction chamber 120, and non-reacted gases and gaseous by-products can then be exhausted out of the reaction chamber via the gas exhaust assembly 165. In another embodiment, the gas supply tube 161 and/or the gas exhaust tube 169 can be made of any suitable material, such as a ceramic material to prevent contamination and unwanted metal oxidation reaction.

As shown in FIGS. 1A-1C, the heating assembly 130 is employed to cover and surround an outer portion of the reaction chamber 120. In one embodiment, the heating assembly 130 can be supported on top of the support platform 190. The heating assembly 130 is used to provide heating energy and structural support to a portion of the reaction chamber 120.

The heating assembly may include a frame 132, an insulation body 134, one or more heating elements surrounding a portion of the outer tube 124 of reaction chamber 120. For example, one or more heating elements 135 may be positioned in an upper portion of the heating assembly 130 and one or more heating elements 136 in a bottom portion of the heating assembly. Similarly, the heating elements 135, 136 may be positioned in right-sided and left-sided portions of the heating assembly 130 to cover and surround a majority of a middle section of the reaction chamber 120.

The frame 132 is in a rectangular solid shape and may be made of a metal-containing material, such as stainless steel or other metal materials. The frame 132 is adapted to enclose the insulation body 134 and provide structural support to the heating assembly 130. The insulation baby 134 is made of a thermal insulation material and adapted to surround the outer portion of the reaction chamber 120. The heating elements 135 and the heating elements 136 are positioned to cover and around the outer tube 124 of the reaction chamber 120. As illustrated in FIGS. 1A-1C, for example, the heating element 135 may be positioned near or about a top portion of the outer tube 124 of the reaction chamber 120; while the heating element 136 may be positioned near or about a bottom portion of the outer tube 124 of the reaction chamber 120. The one or more heating elements 135, 136 can be made of heating coils or heating tubes and adapted to provided heating energy to the reaction chamber 120.

The heating assembly 130 could be divided into one or more heating zones (e.g., Zone A, Zone B, and Zone C, etc.) within the reaction chamber 120 for processing the one or more solid compounds 115 at one or more heating zone temperatures between 30° C. and 1,000° C., which can be sensed and controlled by one or more temperature sensors 133, 137, corresponding to one or more heating elements 135, 136, respectively. The heating energy generated by the heating elements 135, 136 is first conducted to the outer tube 124 of the reaction chamber 120, the heating energy absorbed by the outer tube 124 can then be conducted to the inner tube 122 of the reaction chamber 120. Then, the energy absorbed by the inner tube 122 is conducted to the chamber housing 121 inside the reaction chamber 120 for processing battery materials.

In one example, the heating assembly 130 can be divided into three portions of heating zones 138A. 138B, 138C for processing at various medium and high temperature ranges by using the temperature sensors 133, 137, positioned near one or more sections of the heating assembly 130 within each heating zone to control the heating elements 135, 136. Each of the heating elements 133, 137 are adapted to provide different levels of heating energy to one or more heating zones 138A, 138B, and 138C within the heating assembly 130, resulting in the one or more heating zones to be at different temperatures during processing of the one or more battery material, i.e., the solid compounds 115.

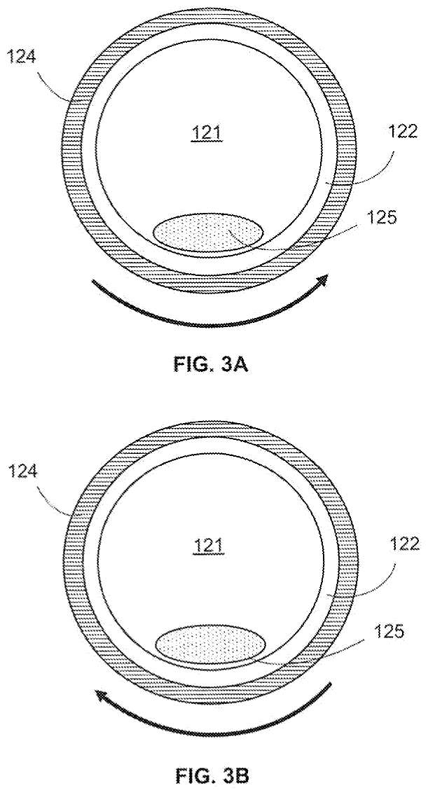

In another example, the temperature range of zone A can be set at a processing temperature of 200° C. or higher, e.g., between 500° C. and 750° C., and the one or more solid compounds 115 may remain in Zone A for a processing time period of 5 minutes or longer, such as from 10 minutes to three hours. It is contemplated that battery material processing at Zone A within the reaction chamber 120 is served to decompose the solid compounds 115, water, and sodium chloride within the solid compounds 115 and turn the solid compounds 115 into a decomposed product mixture, e.g., a mixture 125 (shown in FIG. 3A).

In still another example, the temperature range of Zone B can be set at set at a processing temperature of 300° C. or higher, e.g., between 700° C. and 800° C., and the mixtures 125 would remain in Zone B for a processing time period of 10 minutes or longer, such as from three hours or longer, e.g., between six hours and fifteen hours. It is contemplated that battery material processing at Zone B within the reaction chamber 120 is served to change the chemical state of the mixtures 125 from disordered structure into properly-crystallized processed material particles, e.g., particles 175.

In still another example, the temperature range of Zone C can be set at any suitable processing temperatures, e.g., at 200° C. or higher, e.g., between 500° C. and 750° C., such as between 500° C. to 600° C. to help further annealing and crystallization for the mixture 125 moving continuously from Zone A, Zone B to Zone C inside the chamber housing 121. For example, battery materials can be processed within in Zone C for 10 minutes or longer, such as from one hour to two hours.

In yet another example, the temperature range of Zone C can be set at a temperature provided to cool the temperature of the processed battery materials. For example, processed battery material particles, e.g., the particles 175 may remain in Zone C served to cool the processed battery materials (e.g., the particles 175) and to stabilize the crystal structure of the particles 175. After the cooling process, the processed battery materials contain fine powers of an oxidized form of the composition of the solid compounds 115 (e.g., a metal oxide material, such as fine powers of a mixed metal oxide material, or particles 175 with desired crystal structure, particle size, and morphology, etc.) Accordingly, high quality and consistent active battery materials can be obtained with much less time, labor, and supervision than materials prepared from conventional manufacturing processes.

As shown in FIG. 1A-1C, the collection assembly 170 of the processing system 100 is connected to a rear end of the reaction chamber 120, and the collection assembly 170 includes one or more collection chambers 176 having one or more collection funnels 172, and one or more collection buckets 173 therein. In one embodiment, the collection funnels 172 and the collection buckets 173 can be made of a nickel-containing material. In another embodiment, the nickel-containing material is nickel at high purity, such as at a purity of more than 95% pure nickel, or 99% nickel or 100 pure nickel, among others. Not wishing to be bound by theory, it is contemplated that traditional stainless-steel material may easily be reacted to the processed battery materials, and the use of a nickel-containing material as the materials for the collection funnels 172 and the collection buckets 173 are employed in order to prevent unwanted reaction and accumulation of contaminations and impurities, etc., among others.

After the solid compounds 115 being processed inside the reaction chamber 120, the processed battery materials (e.g., particles 175) are collected by the collection buckets 173 through the collection funnels 172. The connection between the rear end of the reaction chamber 120 and the collection assembly 170 can be sealed by a sealing mechanism, e.g., a rear-end seal 128, or other type of seals, etc., to ensure that pressure within the chamber housing 121 can be controlled during battery material processing, while keeping the reaction chamber 120 in clockwise or counterclockwise rotational motions.

Optionally, one or more cooling elements 129 are provided to cool the temperature of the reaction chamber near its rear end and served to cool processed battery materials inside the reaction chamber 120 and to stabilize the crystal structure of processed battery materials. After the cooling process, the crystallization products contain fine powers of an oxidized form of the composition, for example, a metal oxide material, such as fine powers of a mixed metal oxide material, such as the particles 175, with desired crystal structure, particle size, and morphology.

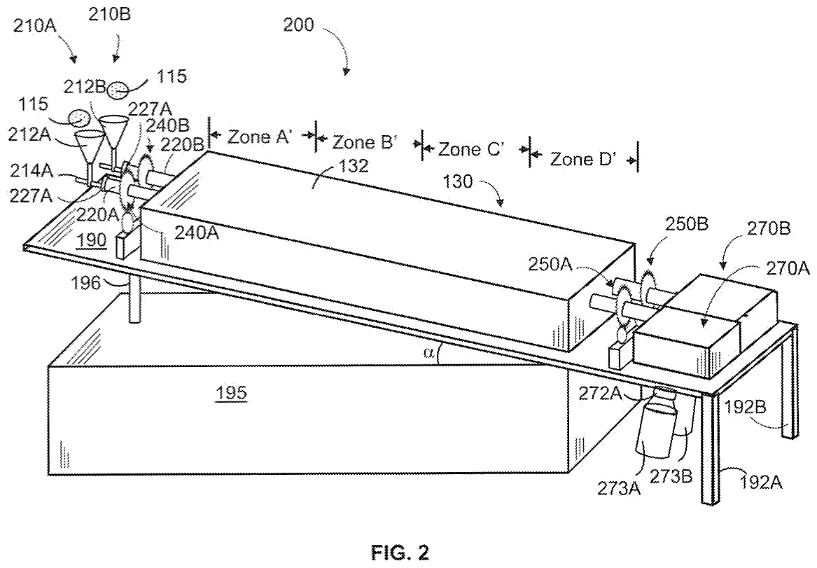

FIG. 2 is a perspective view of another exemplary processing system, a processing system 200, according to another embodiment. The processing system 200 may include two or more reaction chambers 220A, 220B, which uses separate or shared components for processing battery materials. For example, the processing system 200 may include two or more feeder assemblies 210A, 210B, two or more front gear assemblies 240A, 240B, two or more rear gear assemblies 250A, 250B, and two or more collection assemblies 270A, 270B. Some of the system may employ a shared component during processing of battery materials, for example, the heating assembly 130 may be used to provide heat and energy to some or all of the two or more reaction chambers 220A, 220B.

As shown in FIG. 2, in one example, the processing system 200 may be positioned above a base support 195. The two or more reaction chambers 220A, 220B and the heating assembly 130 may be positioned and supported on top of the base support 195, and one side of the base support 195 may be lifted up vertically by the lift mechanism 196, which may be connected to the base support 195 and adapted to lift the support platform 190 at a angle, which may be at a degree of more than 0° and no more than 10°. The purpose for lifting the processing system 200 is to motivate the movement of the solid compounds 115 through the processing system 200. Optionally, two platform legs 192 are connected to the rear side of the support platform 190 and adapted to lift the support platform 190 from the ground and support the rear portion of the support platform 190.

As illustrated in FIG. 2, the feeder assemblies 210A, 210B can be placed in the same vertical position, and parallel to each other. Also, the reaction chambers 120A and 120B can be placed at the same horizontal level, and parallel to each other. The feeder assembly 210A, 210B are connected to the reaction chamber 220A, 220B, respectively. The reaction chamber 220A and 220B are supported by the front gear assembly 240A, 240B, respectively, at their front-end portions, and by the rear gear assembly 250A, 250B, respectively, at their rear end portions. The reaction chamber 220A and 220B are positioned on top of the support platform 190 and are adapted to rotate in a rotational movement around a center axis within each of its chamber housing.

As illustrated in FIG. 2, the heating assembly 130 can be divided into multiple heating zones, such as four heating zones: Zone A′, Zone B′, Zone C′, and Zone D′, or more Zones. In FIG. 2, there are two sets of collection assemblies 270A, 270B, connected the reaction chambers 220A, 220B and adapted to collection one or more processed battery materials, i.e., the particles 175, from each of the reaction chambers 220A, 220B. Alternatively, a share collection assembly can also be used.

FIGS. 3A-3B illustrate an enlarged front cross-sectional view of one example of the reaction chamber 120, showing the outer tube 124 in circular shape and the inner tube 122 in circular shape, enclosing the chamber housing 121 with the mixture 125 of the battery materials in processing inside the chamber housing 121. The reaction chamber 120 may rotates in a counterclockwise rotational movement around a center axis within the chamber housing 121 of the reaction chamber 120 as shown in FIG. 3A, and in a clockwise rotational movement around a center axis within the chamber housing 121 of the reaction chamber 120, as shown in FIG. 38.

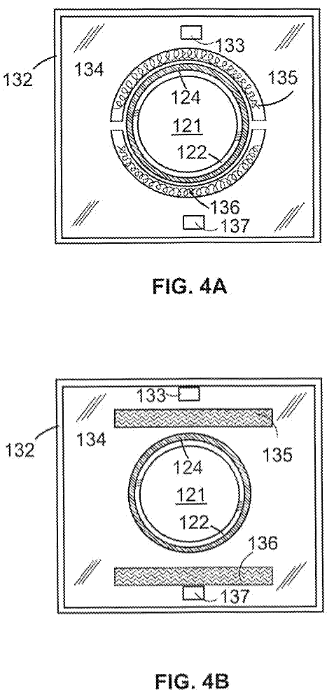

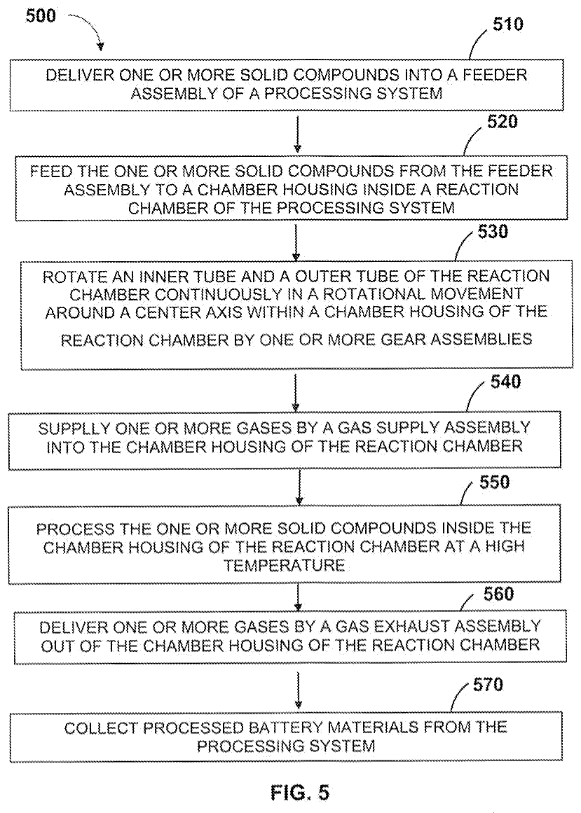

FIG. 4A illustrates an enlarged front cross-sectional view of one example of the heating assembly 130, surrounding the inner tube 122 and outer tube 124 of the reaction chamber 120. In one embodiment, the heating elements of the heating assembly may be made of heating coils in half-circular shape, to form one or more heating elements 135A positioned near an upper portion of the heating assembly 130, and one or more heating elements 136A positioned near a lower portion of the heating assembly 130. The heating elements 135A surrounds a top part of the reaction chamber 120; while the heating element 136A surrounds a bottom part of the reaction chamber 120. In one example, the frame 132 of the heating assembly 130 may be in a rectangular shape. As shown in FIG. 4A, one or more sensors (e.g., the temperature sensors 133, 137) may be positioned about or near the heating elements 135A, 136A, respectively.

FIG. 4B illustrates an enlarged front cross-sectional view of another example of the heating assembly 130. For example, the heating elements of the heating assembly may be formed in blocks or in rectangular shape. As shown in FIG. 4B, one or more heating elements 135B are positioned near an upper portion of the heating assembly 130, and one or more heating elements 136B are positioned near a lower portion of the heating assembly 130. The heating elements 135B are used to heat a top portion of the reaction chamber 120; while the heating element 136B are used to heat a bottom portion of the reaction chamber 120. Since the reaction chamber 120 is rotating, thus, the heat energy provided by the heating element 135B, 136B can then be used to evenly heat the circumference of the chamber housing 121 of the reaction chamber 120. As shown in FIG. 4B, one or more sensors (e.g., the temperature sensors 133, 137) may be positioned about or near the heating elements 1358, 136B, respectively.

FIG. 5 illustrates one embodiment of a flow chart of a method 500 of preparing a battery material using one or more processing systems of the invention. Firstly, at step 110 of the method 500, one or more solid compounds 115 are continuously delivered into a feeder assembly 110 of a processing system 100. For example, the one or more solid compounds 115 can be delivered manually (e.g., in separate batches) or continuously (e.g., batch by batch one after another or by an automation machinery) via the feeder inlet 111.

At step 520, the one or more solid compounds 115 are fed from the feeder assembly 110 into the chamber housing 121 inside a reaction chamber 120 of the processing system 100 to be processed inside the chamber housing of the reaction chamber. For example, the spiral rod 116 within the feeder tube 114 is adapted to be rotating for feeding and carrying the one or more solid compounds 115 into the reaction chamber 120 (e.g., inside the chamber housing 121). The motor 119 is connected to one end of the feeder tube 114 to control the rotational movement of the spiral rod 116 within the feeder tube 114.

Next, at step 530, the inner tube and the outer tube of the reaction chamber are rotated dynamically and continuously in a rotational movement around a center axis within the chamber housing of the reaction chamber by one or more gear assemblies. For example, the front gear assembly 140 and the rear gear assembly 150, both being connected to the outer tube 124 of the reaction chamber 120, are adapted to work together and rotate the reaction chamber 120 in a rotational movement around a center axis (e.g., LINE C-C′) within the chamber housing 121 of the reaction chamber 120. The front gear assembly 140 of the processing system 100 is positioned near a front-end portion of the reaction chamber 120; while the rear gear assembly 150 is positioned near a rear-end portion of the reaction chamber 120 for supporting the weight and movement of the reaction chamber 120. One or both of the motors 147, 157 may be used to drive the movement of one or more gears for rotating the inner tube 122 and the outer tube 124 of the reaction chamber 120 of the processing system 100, e.g., around a center axis (Line C-C′) within the chamber housing 121 of the reaction chamber 120 to control the rotational movement of the outer tube 124 and inner tube 122 of the reaction chamber 120 through the one or more gears 142, 144, 152, 154.

At step 540, one or more gases are supplied by a gas supply assembly into the chamber housing of the reaction chamber. For example, the gas supply assembly 160 may be disposed at the front or rear end of the reaction chamber 120 to supply one or more gases into the chamber housing 121 of the reaction chamber 120 to assist in complete processing and crystallization of material particles being processed inside the chamber housing.

At step 550, one or more solid compound are processed inside the chamber housing of the reaction chamber at a high temperature. For example, the heating assembly 130 may be used to provide heating energy to a large portion of the reaction chamber 120 for battery material processing at a processing temperature range of between 200° C. and 1,000° C. As another example, the heating assembly 130 may be divided into heating zones (Zone A, Zone B, and Zone C, Zone A′, Zone B′, and Zone C′, Zone D′, etc., for high yield battery material processing.

At step 560, one or more gases are delivered out of a gas exhaust assembly of the reaction chamber. For example, the gas exhaust assembly 165, being disposed at the front or rear end of the reaction chamber 120, and extending into the chamber housing 121 of the reaction chamber 120, may be used to deliver one or more non-reacted gases, gaseous side products and/or contaminants out of the chamber housing 121 of the reaction chamber 120.

Finally, at step 570, processed battery materials are collected from the processing system. For example, the collection assembly 170, being connected to the rear end of the reaction chamber 120; can be used to collect the particles 175 and/or the processed battery materials 175 from the reaction chamber 120. Accordingly, high quality and consistent active battery materials can be obtained with much less time, labor, and supervision than materials prepared from conventional manufacturing processes.

While the foregoing is directed to embodiments of the present invention, other and further embodiments of the invention may be devised without departing from the basic scope thereof, and the scope thereof is determined by the claims that follow.

What is claimed:

1. A processing system for manufacturing battery materials, comprising:
a reaction chamber, comprising:
an outer tube comprising a stainless-steel material;
an inner tube comprising a ceramic material; and
a chamber housing being enclosed by the inner tube and provided for processing one or more solid compounds;
a feeder assembly being sealably connected to a front end of the reaction chamber and adapted to deliver the one or more solid compounds into the chamber housing within the reaction chamber;
a heating assembly being adapted to cover and surround an outer portion of the reaction chamber, provide heating energy and structural support to the reaction chamber; and
one or more gear assemblies being connected to the outer tube and adapted to rotate the reaction chamber so that the inner tube and the outer tube of the reaction chamber being in a rotational movement around a center axis within the chamber housing of the reaction chamber.

2. The processing system of claim 1, wherein the inner tube of the reaction chamber comprises alumina ceramics, aluminum oxide (Al₂O₃), more than 90% purity of alumina.

3. The processing system of claim 1, further comprising a collection assembly being sealably connected to a rear end of the reaction chamber and adapted to collect one or more processed battery materials from the reaction chamber

4. The processing system of claim 1, wherein the feeder assembly further comprising:
a feeder bucket adapted to receive the one or more solid compounds; and
a feeder tube having a spiral rod therein, wherein the feeder tube is connected to the feeder bucket and adapted to receive the one or more solid compounds from the feeder bucket, wherein the spiral rod is adapted to be rotating for carrying the one or more solid compounds into the chamber housing of the reaction chamber.

5. The processing system of claim 1, wherein the feeder tube comprising a nickel material at high purity of more than 95% nickel.

6. The processing system of claim 1, wherein the spiral rod of the feeder tube comprising a nickel material at high purity of more than 95% nickel.

7. The processing system of claim 1, wherein the heating assembly comprising:
an insulation body made of a thermal insulation material and adapted to surround the outer portion of the reaction chamber;
one or more heating elements within the insulation body, wherein the one or more heating elements are positioned around the outer tube of the reaction chamber and adapted to provide heating energy to the reaction chamber; and
a frame adapted to enclose the insulation body and provide structural support to the heating assembly.

8. The processing system of claim 7, wherein the one or more heating elements are adapted to provide different levels of heating energy to one or more heating zones within the reaction chamber, resulting in the one or more heating zones to be at different temperatures during processing of the one or more battery materials.

9. The processing system of claim 1, wherein the heating assembly further comprising one or more temperature sensors to control the temperature within each heating zone.

10. The processing system of claim 1, the one or more gear assemblies further comprising:
a front gear assembly connected to the front end of the reaction chamber and adapted to rotate the reaction chamber, and
a rear gear assembly connected to the rear end of the reaction chamber.

11. The processing system of claim 1, wherein the collection assembly further comprising a collection chamber, a collection funnel and a collection bucket; wherein the collection funnel is inside the collection chamber.

12. The processing system of claim 1, wherein the collection assembly further comprising one or more cooling elements.

13. The processing system of claim 1, further comprising:
a gas supply assembly comprising a gas inlet, a flow rate meter and a gas supply tube for supplying one or more gases into the chamber housing of the reaction chamber; and
a gas exhaust assembly comprising a gas outlet, a gas exhaust rate meter and a gas exhaust tube for delivering one or more gases out of the chamber housing of the reaction chamber.

14. The processing system of claim 13, wherein the gas supply tube comprises a ceramic material.

15. The processing system of claim 13, wherein the gas exhaust tube comprises a ceramic material.

16. The processing system of claim 1, further comprising one or more cooling elements connected to the rear end of the reaction chamber and adapted to cool the one or more processed battery materials.

17. The processing system of claim 1, further comprising a support platform adapted to support the reaction chamber of the processing system.

18. The processing system of claim 1, further comprising a lift mechanism connected to the support platform and adapted to lift the support platform at an α angle of more than 0° and no more than 10°.

19. A processing system for manufacturing battery materials, comprising:
a reaction chamber, comprising:
an outer tube comprising a stainless-steel material;
an inner tube comprising a ceramic material; and
a chamber housing being enclosed by the inner tube and provided for processing one or more solid compounds;
a feeder assembly being sealably connected to a front end of the reaction chamber and adapted to deliver the one or more solid compounds into the chamber housing within the reaction chamber;
a heating assembly being adapted to cover and surround an outer portion of the reaction chamber, provide heating energy and structural support to the reaction chamber;
one or more gear assemblies being connected to the outer tube and adapted to rotate the inner tube and the outer tube of the reaction chamber in a rotational movement around a center axis within the chamber housing of the reaction chamber;
a collection assembly being sealably connected to a rear end of the reaction chamber and adapted to collect processed battery materials from the reaction chamber;
a gas supply assembly comprising a gas inlet and a gas supply tube for supplying one or more gases into the chamber housing of the reaction chamber; and
a gas exhaust assembly comprising a gas outlet and a gas exhaust tube being made of a ceramic material for delivering one or more gases out of the chamber housing of the reaction chamber.

20. The processing system of claim 19, the one or more gear assemblies further comprising:
a front gear assembly connected to the front end of the reaction chamber and adapted to rotate the reaction chamber, and
a rear gear assembly connected to the rear end of the reaction chamber.

21. The processing system of claim 19, wherein the gas supply tube comprises a ceramic material.

22. The processing system of claim 19, wherein the gas exhaust tube comprises a ceramic material.

23. The processing system of claim 19, further comprising:
a support platform adapted to support the reaction chamber of the processing system; and
a lift mechanism connected to the support platform and adapted to lift the support platform at an α angle of more than 0° and no more than 10°.

24. A processing system for manufacturing battery materials, comprising:
a reaction chamber, comprising:
an outer tube comprising a stainless-steel material;
an inner tube comprising a ceramic material; and
a chamber housing being enclosed by the inner tube and provided for processing one or more solid compounds;
a feeder assembly being sealably connected to a front end of the reaction chamber and adapted to deliver the one or more solid compounds into the chamber housing within the reaction chamber;
a heating assembly being adapted to cover and surround an outer portion of the reaction chamber, provide heating energy and structural support to the reaction chamber;
one or more gear assemblies being connected to the outer tube and adapted to rotate the inner tube and the outer tube of the reaction chamber in a rotational movement around a center axis within the chamber housing of the reaction chamber;
a collection assembly being sealably connected to a rear end of the reaction chamber and adapted to collect processed battery materials from the reaction chamber;
a support platform being adapted to support the reaction chamber of the processing system; and
a lift mechanism being connected to the support platform and adapted to lift the support platform at an α angle; wherein the α angle is more than 0° and no more than 10°.

25. The processing system of claim 24, wherein the feeder assembly comprising:
a feeder bucket adapted to receive the one or more solid compounds; and
a feeder tube having a spiral rod therein, wherein the feeder tube is connected to the feeder bucket and adapted to receive the one or more solid compounds from the feeder bucket, wherein the spiral rod is adapted to be rotating for carrying the one or more solid compounds into the chamber housing of the reaction chamber.

26. The processing system of claim 25, wherein the feeder tube comprising a nickel material at high purity of more than 95% nickel.

27. The processing system of claim 25, wherein the spiral rod of the feeder tube comprising a nickel material at high purity of more than 95% nickel.

28. The processing system of claim 24, wherein the lift mechanism connected to the support platform and adapted to lift the support platform at a angle of between 2° and and 7°.
